(19) United States
(12) Patent Application Publication
(10) Pub. No.: US 2026/0006999 A1
(43) Pub. Date: Jan. 1, 2026

(54) DISPLAY MODULE INCLUDING A BENDING AREA

(71) Applicant: SAMSUNG DISPLAY CO., LTD., YONGIN-SI (KR)

(72) Inventors: JONGHOON CHOI, Yongin-si (KR); DOKEUN SONG, Yongin-si (KR); YEONGWOO KWON, Yongin-si (KR); HYOUNG SIK KIM, Yongin-si (KR)

(21) Appl. No.: 19/189,331

(22) Filed: Apr. 25, 2025

(30) Foreign Application Priority Data
Jun. 26, 2024 (KR) 10-2024-0083759
Jul. 29, 2024 (KR) 10-2024-0100367

(51) Int. Cl. H10K 59/122; H10K 59/131; H10K 59/80; H10K 77/10; H10K 102/00

(52) U.S. Cl. CPC H10K 59/122; H10K 59/131; H10K 59/80521; H10K 77/111; H10K 2102/351

(57) ABSTRACT

A display module includes a base layer on which a first area, a bending area, and a second area are defined, a circuit element layer disposed on the base layer and including a conductive pattern and insulating layers covering the conductive pattern, and a display element layer disposed on the circuit element layer. The display element layer includes a pixel defining layer disposed on the circuit element layer, having a light-emitting opening in an area overlapping the first area, a partition wall disposed on the pixel defining layer and having a partition wall opening overlapping the light-emitting opening, and a light-emitting element including a cathode that is in contact with the partition wall and disposed in the light-emitting opening and the partition wall opening, wherein the partition wall overlapping the bending area is connected to the conductive pattern through a contact hole passing through the insulating layers.

### CROSS-REFERENCE TO RELATED APPLICATIONS

This application claims priority under 35 U.S.C. § 119 to Korean Patent Application No. 10-2024-0083759, filed on Jun. 26, 2024, in the Korean Intellectual Property Office, and Korean Patent Application No. 10-2024-0100367, filed on Jul. 29, 2024, in the Korean Intellectual Property Office, the entire contents of which are hereby incorporated by reference.

### BACKGROUND

### 1. Technical Field

The present disclosure herein relates to a display module including a bending area and an electronic device, and more particularly, to a display module including a partition wall provided in a bending area, and an electronic device.

### 2. Discussion of Related Art

Electronic devices such as televisions, monitors, smartphones, and tablets may include display panels configured to display images. Various display panels have been developed, such as liquid crystal display panels, organic light emitting panels, electro wetting display panels, and electrophoretic display panels.

The display panels may include a bending area, which may refer to a region of the display panel that may be bent, rolled, or folded. The bending area may be subject to damage, such as cracks in wiring.

### SUMMARY

The present disclosure provides a display module, in which cracks may be inhibited or prevented, and an electronic device in a display panel in which a light-emitting element may be defined by a partition wall.

An embodiment of the inventive concept provides a display module including: a base layer on which a first area, a bending area, and a second area are defined along one direction; a circuit element layer disposed on the base layer, the circuit element layer including a conductive pattern and insulating layers configured to cover the conductive pattern; and a display element layer disposed on the circuit element layer, wherein the display element layer includes: a pixel defining layer disposed on the circuit element layer, having a light-emitting opening in an area overlapping the first area; a partition wall disposed on the pixel defining layer and having a partition wall opening overlapping the light-emitting opening; and a light-emitting element including an anode, a light-emitting pattern, and a cathode that is in contact with the partition wall and disposed in the light-emitting opening and the partition wall opening, wherein the partition wall overlapping the bending area is connected to the conductive pattern through a contact hole passing through the insulating layers of the circuit element layer.

In an embodiment, the base layer may include a display area and a non-display area adjacent to the display area, and the first area corresponds to the display area and a portion of the non-display area, and the bending area and the second area correspond to the non-display area.

In an embodiment, the partition wall may be electrically connected to the cathode in the display area.

In an embodiment, the partition wall may have an integrated shape on the display area.

In an embodiment, the partition wall and the conductive pattern may be patterned to provide a first signal line and a second signal line that is electrically disconnected from the first signal line.

In an embodiment, the first signal line and the second signal line may be spaced apart from each other.

In an embodiment, the partition wall overlapping the bending area may be electrically disconnected from the cathode.

In an embodiment, the circuit element layer may include a plurality of insulating layers, and a groove that overlaps the bending area is defined in each of a plurality of insulating layers.

In an embodiment, the conductive pattern may include a first conductive pattern and a second conductive pattern disposed on the first conductive pattern, and the insulating layers may include a first insulating layer configured to cover the first conductive pattern and a second insulating layer configured to cover the second conductive pattern, wherein the second conductive pattern may be connected to the first conductive pattern through a first contact hole defined in the first insulating layer, and the partition wall may be connected to the second conductive pattern through a second contact hole defined in the second insulating layer.

In an embodiment, the partition wall and the conductive pattern may include a same conductive material.

In an embodiment, each of the partition wall and the conductive pattern may include at least one of titanium (Ti), aluminum (Al), molybdenum (Mo), or titanium nitride (TIN).

In an embodiment, the partition wall may include: a first partition wall layer disposed on the pixel defining layer and defining the partition wall opening; and a second partition wall layer disposed on the first partition wall layer, wherein the second partition wall layer may include an upper tip portion protruding from the first partition wall layer into the partition wall opening.

In an embodiment, the first partition wall layer may have an undercut shape with respect to the second partition wall layer.

In an embodiment, the display module may further include a thin film encapsulation layer disposed on the display element layer, wherein the thin film encapsulation layer may include: a lower inorganic encapsulation pattern configured to cover the light-emitting element; an organic encapsulation layer disposed on the lower inorganic encapsulation pattern; and an upper inorganic encapsulation layer disposed on the organic encapsulation layer.

In an embodiment of the inventive concept, an electronic device includes: a display module on which a first area, a bending area, and a second area are defined along one direction; a window disposed on the display module; and a housing disposed below the display module and coupled to the window to provide an internal space; wherein the display module includes: a circuit element layer including a conductive pattern and insulating layers configured to cover the conductive pattern; a pixel defining layer disposed on the circuit element layer and having a light-emitting opening in an area overlapping the first area; a partition wall disposed on the pixel defining layer and having a partition wall opening overlapping the light-emitting opening; and a light-emitting element including an anode, a light-emitting pattern, and a cathode that is in contact with the partition wall and disposed within the light-emitting opening and the partition wall opening, wherein the partition wall and the conductive pattern are patterned to provide a first signal line and a second signal line that is electrically disconnected from, and spaced apart from, the first signal line.

In an embodiment, the display module may include a display area and a non-display area adjacent to the display area, the first area corresponds to the display area and a portion of the non-display area, and the bending area and the second area correspond to the non-display area, and in the display area, the partition wall has an integrated shape and is electrically connected to the cathode.

In an embodiment, the circuit element layer may include a plurality of insulating layers, and a groove that overlaps the bending area may be defined in each of a plurality of insulating layers.

In an embodiment, the partition wall and the conductive pattern may include a same conductive material.

In an embodiment, the partition wall may include a first partition wall layer defining the partition wall opening and disposed on the pixel defining layer and a second partition wall layer disposed on the first partition wall layer, wherein the second partition wall layer may include an upper tip portion protruding from the first partition wall layer into the partition wall opening.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a perspective view of an electronic device according to an embodiment of the inventive concept;

FIG. 1B is an exploded perspective view of the electronic device according to an embodiment of the inventive concept;

FIG. 2 is a cross-sectional view of the electronic device according to an embodiment of the inventive concept;

FIG. 3 is a cross-sectional view of a display module according to an embodiment of the inventive concept;

FIG. 4 is a plan view of the display module according to an embodiment of the inventive concept;

FIG. 5 is a plan view enlarging a portion of a display area of the display module according to an embodiment of the inventive concept;

FIG. 6 is a cross-sectional view of the display panel taken along line I-I′ shown in FIG. 4;

FIG. 7 is a cross-sectional view of the display panel taken along line II-II′ shown in FIG. 4; and

FIG. 8 is a diagram illustrating an electronic device according to an embodiment of the inventive concept.

### DETAILED DESCRIPTION

It will be understood that when an element or layer is referred to as being “on”, “connected to” or “coupled to” another element or layer, the element or layer can be directly on, connected or coupled to the other element or layer or intervening elements or layers may be present.

Like numbers refer to like elements throughout. The thickness and the ratio and the dimension of the element may be exaggerated for effective description of the technical contents. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish elements, components, regions, layers or sections from each other. Thus, a first element, component, region, layer or section discussed below could be referred to as a second element, component, region, layer or section, and vice versa without departing from the teachings of the inventive concept. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe an element or feature's relationship to another element(s) or feature(s) as illustrated in the figures. The terms are relative concepts and are described based on the direction shown in the drawings.

It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the inventive concept will be explained in detail with reference to the accompanying drawings.

In an embodiment, in a display panel may include a partition wall of a display element layer that is electrically connected to a light-emitting element and used as wiring to connect conductive patterns of a circuit element layer in a bending area. A curvature radius of the bending area may be increased by the thickness of a pixel defining layer disposed under the partition wall. In a case that the curvature radius is increased a tensile force acting on the bending area of the display module may be reduced, and cracks occurring in the bending area may be decreased or eliminated. For example, the tensile force acting on the bending region of the display module can be reduced, and cracks occurring in the bending region can be reduced or eliminated.

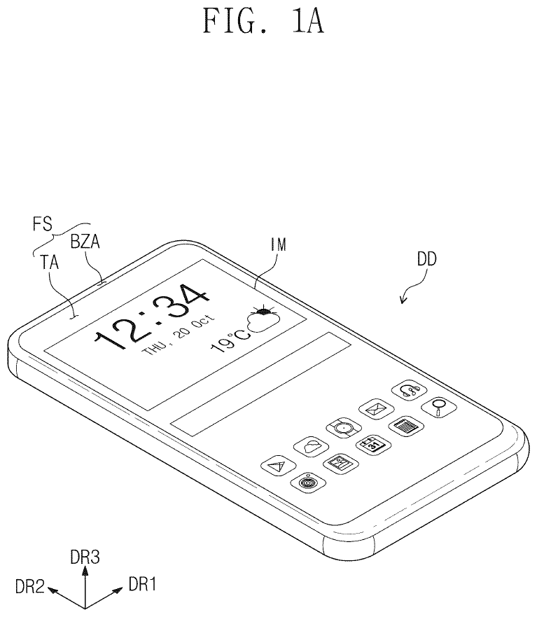

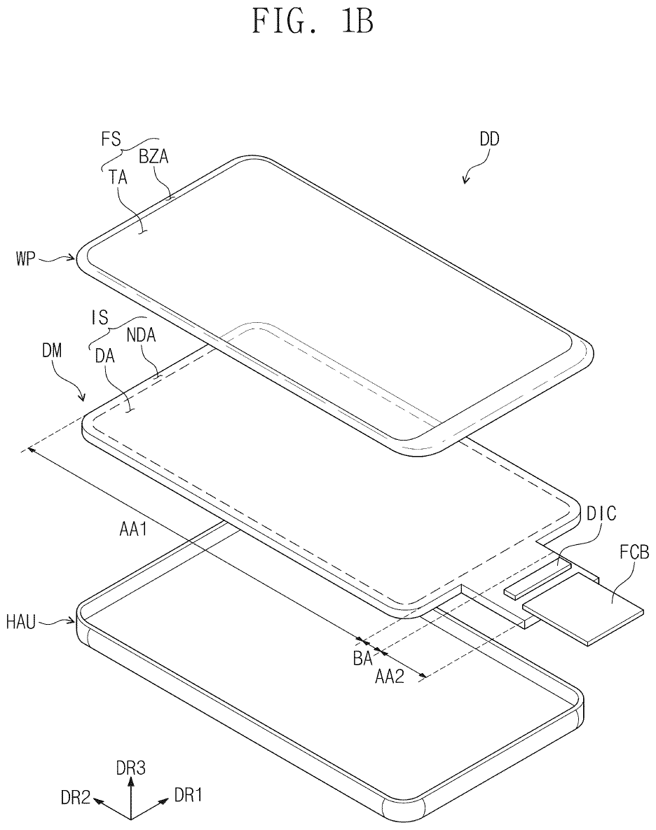

FIG. 1A is a perspective view of an electronic device DD according to an embodiment of the inventive concept. FIG. 1B is an exploded perspective view of the electronic device DD according to an embodiment of the inventive concept.

In an embodiment, the electronic device DD may be an electronic device such as a television, a monitor, or billboard. Additionally, the electronic device DD may be an electronic device such as a personal computer, a laptop computer, a personal digital assistant, a car navigation unit, a gaming console, a smartphone, a tablet, or a camera. However, these are only examples, and other electronic devices may be adapted without departing from the spirit of the inventive concept. In FIG. 1A and FIG. 1B, for example, the electronic device DD is a smartphone.

Referring to FIG. 1A and FIG. 1B, the electronic device DD may display an image IM in a third direction DR3 on a display surface FS, which may be parallel to each of a first direction DR1 and a second direction DR2. The image IM may include a dynamic image or a still image. In FIG. 1A, a clock window and icons are illustrated as an example of the image IM. The display surface FS that displays the image IM may correspond to a front surface of the electronic device DD.

In an embodiment, a front surface (or a top surface) and a rear surface (or a bottom surface) of each part may be defined based on a direction in which the image IM is displayed. The front surface and the rear surface may be opposite to each other in the third direction DR3, and a normal direction of each of the front and rear surfaces may be parallel to the third direction DR3. The directions indicated by the first to third directions DR1, DR2, and DR3 are relative concepts and may be transformed into other directions. In this specification, “on a plane” may refer to the view when looking from the third direction DR3.

The electronic device DD may include a window WP, a display module DM, and a housing HAU. The window WP and the housing HAU may be coupled together to provide an exterior of the electronic device DD.

The window WP may include an optically transparent insulating material. For example, the window WP may include glass or plastic. The front surface of the window WP may define the display surface FS of the electronic device DD. The display surface FS may include a transmission area TA and a bezel area BZA. The transmission area TA may be an optically transparent area. For example, the transmission area TA may be an area having a visible light transmittance of about 90% or more.

The bezel area BZA may be an area having a relatively lower light transmittance compared to the transmission area TA. For example, the bezel area BZA may be defined by an ink printed on the display surface FS. The bezel area BZA may define a shape of the transmission area TA. The bezel area BZA may be adjacent to and surround the transmission area TA. However, it is only an example, and the bezel area BZA of the window WP may be omitted. For example, the transmission area TA may have the same dimensions as the display surface FS. The window WP may include at least one functional layer of a fingerprint-resistant layer, a hard coating layer, or an anti-reflective layer, and the window WP is not limited thereto.

The display module DM may function as an output device that may display images and as an input device may detect inputs applied from the outside. The display module DM may be disposed below the window WP. The display module DM may be configured to generate the image IM. The image IM generated from the display module DM may be displayed on a display surface IS of the display module DM and may be visible to the user from the outside through the transmission area TA.

The display module DM may include a display area DA and a non-display area NDA. The display area DA may be an area that may be activated in response to electrical signals. The non-display area NDA may be adjacent to the display area DA. The non-display area NDA may surround the display area DA. The non-display area NDA may be an area at least partially covered by the bezel area BZA and may not be visible from the outside. The display area DA of the display module DM may correspond to at least portion of the transmission area TA of the window WP, and the non-display area NDA of the display module DM may correspond to at least portion of the bezel area BZA.

The display module DM may include a first area AA1, a bending area BA adjacent to the first area AA1, and a second area AA2 adjacent to the bending area BA. That is, the first area AA1, the bending area BA, and the second area AA2 may be defined along one direction (for example, direction opposite to the second direction DR2). The first area AA1 may correspond to a part of the display area DA and the non-display area NDA, while the bending area BA and the second area AA2 may correspond to the non-display area NDA. The bending area BA may be defined between the first area AA1 and the second area AA2. In a case that the electronic device DD is a foldable device, the first area AA1 and the second area AA2 may be bent, folded, or rolled. In at least one embodiment, the first area AA1 may be a first non-bending area and the second area AA2 may be a second non-bending area.

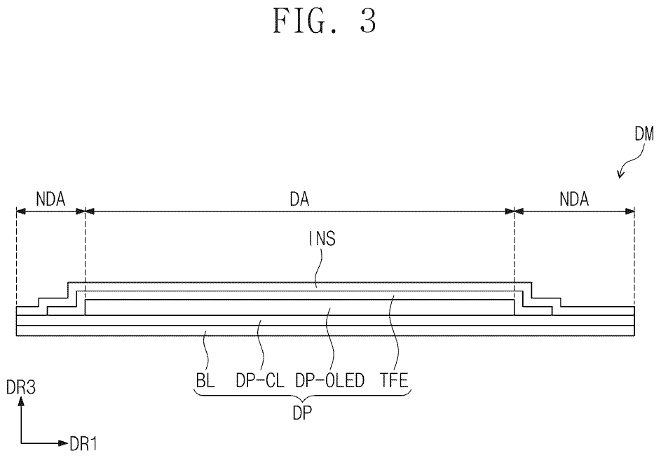

The display module DM may include a display panel DP. The display panel DP may include the display area DA and the non-display area NDA (see FIG. 3). The first area AA1, the bending area BA, and the second area AA2 may be defined on the display panel DP of the display module DM. The display panel DP may include a base layer BL, a circuit element layer DP-CL, a display element layer DP-OLED, and an encapsulation layer TFE.

The first area AA1 may correspond to the display surface IS. That is, the first area AA1 may include an area where the image IM (see FIG. 1A) may be displayed. The bending area BA may be bent so that a rear surface of the first area AA1 faces a rear side of the second area AA2. A plurality of pads may be disposed on the display module DM in the second area AA2.

A driving chip DIC may be disposed on the display module DM in the second area AA2. The driving chip DIC may include driving elements, such as a data driving circuit, for driving the pixels of the display module DM. Although FIG. 1B illustrates a structure in which the driving chip DIC may be mounted on the display panel DP, the disclosure is not limited thereto. For example, the driving chip DIC may be mounted on a flexible circuit board FCB.

The flexible circuit board FCB may be coupled to the display module DM in the second area AA2. The flexible circuit board FCB may be connected to a main circuit board. The main circuit board may be an electronic component to which one or more electronic modules may be attached.

The housing HAU may be coupled to the window WP. The housing HAU may be coupled to the window WP and provide a predetermined internal space. The display module DM may be accommodated in the internal space of the housing HAU.

The housing HAU may include a material having relatively high rigidity. For example, the housing HAU may include glass, plastic, ceramic, or metal, or it may include a plurality of frames and/or plates made of a combination of materials. The housing HAU may reliably protect the components of the electronic device DD accommodated in the internal space from external impacts and/or contaminants.

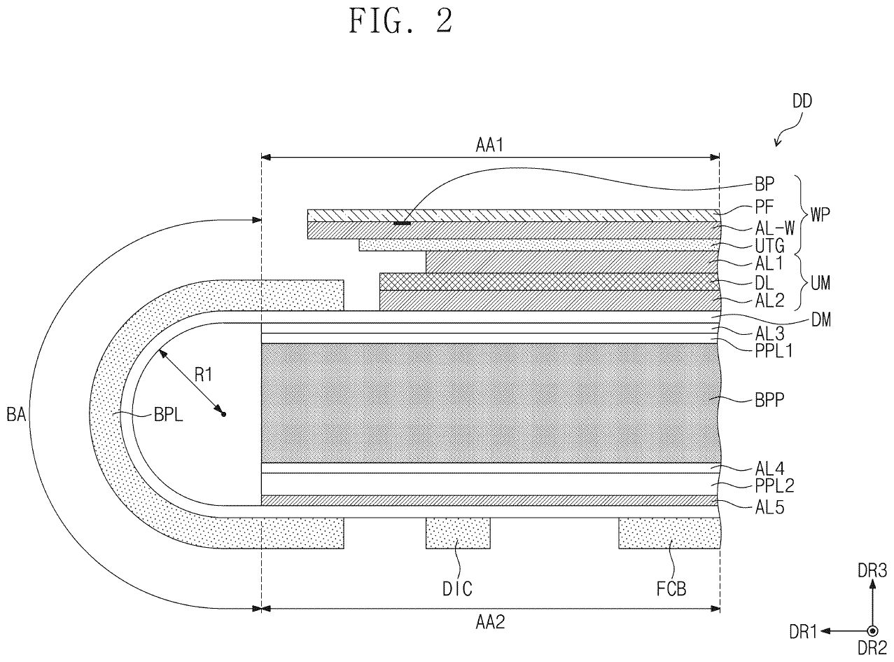

FIG. 2 is a cross-sectional view of the electronic device DD according to an embodiment of the inventive concept. FIG. 2 illustrates the display module DM in a bent state.

Referring to FIG. 1A, FIG. 1B, and FIG. 2, the electronic device DD may include a window WP, an upper member UM, a display module DM, a first protective film PPL1, a lower member BPP, and a second protective film PPL2. The upper member UM may be used as a collective term for components disposed between the window WP and the display module DM.

The window WP may include a glass substrate UTG, a window protective layer PF, a window adhesive layer AL-W, and a bezel pattern BP. The window WP may be disposed to overlap the first area AA1. The glass substrate UT G may be, for example, chemically strengthened glass, sapphire glass, laminated glass, tempered glass, or aluminosilicate glass. In a case that the electronic device DD is a foldable device, the glass substrate UTG may inhibit the formation of wrinkles even when folding and unfolding are repeated.

The window protective layer PF may be disposed on the glass substrate UTG. The window protective layer PF may include a synthetic resin film.

For example, the window protective layer PF may include at least one of polyimide (PI), polycarbonate (PC), polyamide (PA), triacetylcellulose (TAC), polymethylmethacrylate (PMMA), or polyethylene terephthalate (PET). At least one of a hard coating layer, a fingerprint-resistant layer, or an anti-reflective layer may be disposed on a top surface of the window protective layer PF.

The window protective layer PF and the glass substrate UTG may be coupled to each other by a window adhesive layer AL-W. The window adhesive layer AL-W may be a pressure-sensitive adhesive film (PSA) or an optically clear adhesive member (OCA). The adhesive layers described hereafter may also include the same adhesive as the window adhesive layer AL-W.

The bezel pattern B P may be disposed on a bottom surface of the window protective layer PF. The bezel pattern BP may overlap the non-display area NDA shown in FIG. 1A. The bezel pattern BP may be a colored light-shielding film, for example, provided through a coating process. The bezel pattern BP may include a base material and a dye or pigment mixed into the base material. Although the bezel pattern BP disposed on the bottom surface of the window protective layer PF is illustrated in FIG. 2, as an example, the disclosure is not limited thereto. For example, the bezel pattern BP may be disposed on a top surface of the window protective layer PF.

The upper member UM may include an upper film DL. The upper film DL may absorb external impacts applied to the front surface of the electronic device DD. The upper film DL may include a synthetic resin film. The synthetic resin film may include polyimide (PI), polycarbonate (PC), polyamide (PA), triacetylcellulose (TAC), polymethylmethacrylate (PMMA), or polyethylene terephthalate (PET). In an embodiment of the inventive concept, the upper film DL may be omitted.

The upper member UM may include a first adhesive layer AL1 that bonds the upper film DL to the window WP. The upper member UM may include a second adhesive layer AL2 that bonds the upper film DL to the display module DM. Each of the first adhesive layer AL1 and the second adhesive layer AL2 may be a pressure-sensitive adhesive film (PSA) or an optically clear adhesive member (OCA).

The display module DM, in an embodiment of the inventive concept, may include an anti-reflective layer structure that includes a polarizing film or multiple color filters. A detailed description of the display module DM will be provided with reference to FIG. 3.

The first and second protective films PPL1 and PPL2 may be disposed below the display module DM. The first and second protective films PPL1 and PPL2 may protect an area below the display module DM. The first and second protective films PPL1 and PPL2 may include a flexible synthetic resin film. For example, the first and second protective films PPL1 and PPL2 may include polyethylene terephthalate (PET).

In an embodiment of the inventive concept, the first and second protective films PPL1 and PPL2 may not be disposed on the display module DM in the bending area BA. The first protective film PPL1 may be disposed to protect the first area AA1. The second protective film PPL2 may be disposed to protect the second area AA2. When the bending area BA bends, since the first and second protective films PPL1 and PPL2 are not disposed on the display module DM in the bending area BA, the display module DM may bend more easily. A third adhesive layer AL3 may bond the first protective film PPL1 and the display module DM to each other. For example, the third adhesive layer AL3 may bond the first protective film PPL1 to the display module DM in the first area AA1.

The lower member BPP may be disposed below the display module DM. The lower member BPP may include one or more of a support member, a cover layer, a digitizer, an electromagnetic shielding layer, or a metal layer. The lower member BPP may be disposed to overlap the first area AA1 and the second area AA2. A fourth adhesive layer AL4 may bond the lower member BPP to the second protective film PPL2, and a fifth adhesive layer AL5 may bond the second protective film PPL2 to the display module DM. For example, the fifth adhesive layer AL5 may bond the second protective film PPL2 to the second area AA2 of the display module DM. The fifth adhesive layer AL5 and the third adhesive layer AL3 may be bonded to the same surface of the display module DM.

When the display module DM is bent, the bending area BA may have a predetermined curvature and radius of curvature R1. Since the lower member BPP is not disposed in the bending area BA when the bending area BA is bent, the display module DM may be bent more easily.

The electronic device DD may further include a bending protection layer BPL. The bending protection layer BPL may protect the bending area BA of the display module DM during bending. The bending protection layer BPL may overlap the first area AA1, the bending area BA, and the second area AA2. For example, the bending protection layer BPL may overlap a portion of the first area AA1, the bending area BA, and a portion of the second area AA2. The bending protection layer BPL may be disposed on a surface of the display module DM opposite to the surface bonded to the fifth adhesive layer AL5 and the third adhesive layer AL3.

The bending protection layer BPL may bend together with the display module DM. The bending protection layer BPL may protect the bending area BA from external impacts and control a neutral plane of the bending area BA. The bending protection layer BPL may control a stress in the bending area BA so that the neutral plane approaches signal lines disposed in the bending area BA.

FIG. 3 is a cross-sectional view of the display module DM according to an embodiment of the inventive concept.

Referring to FIG. 3, the display module DM may include a display panel DP and an input sensor INS. The electronic device DD (see FIG. 1A) according to an embodiment of the inventive concept may further include a protective member disposed on a the bottom surface of the display panel DP or an anti-reflective member and/or window member disposed on a top surface of the input sensor INS.

The display panel DP may be a light-emitting display panel. However, the light-emitting display panel is only an example, and the inventive concept is not particularly limited thereto. For example, the display panel DP may be an organic light-emitting display panel or an inorganic light-emitting display panel. A light-emitting layer within the organic light-emitting display panel may include organic light-emitting materials. A light-emitting layer within the inorganic light-emitting display panel may include quantum dots, quantum rods, or micro-LEDs. Hereinafter, the display panel DP will be described as an organic light-emitting display panel.

The display panel DP may include a base layer BL, a circuit element layer DP-CL, a display element layer DP-OLED, and a thin film encapsulation layer TFE. The circuit element layer DP-CL may be disposed on the base layer BL. The display element layer DP-OLED may be disposed on the circuit element layer DP-CL. The thin film encapsulation layer TFE may be disposed on the circuit element layer DP-CL and the display element layer DP-OLED. For example, the thin film encapsulation layer TFE may be a conformal layer. The input sensor INS may be directly disposed on the thin film encapsulation layer TFE and the circuit element layer DP-CL. For example, the input sensor INS may be a conformal layer. In this specification, the phrase “Configuration A is directly disposed on Configuration B” means that the adhesive layer is not disposed between Configuration A and Configuration B.

The base layer BL may include at least one plastic film. The base layer BL may be a flexible substrate, including a plastic substrate, a glass substrate, a metal substrate, or an organic/inorganic composite material substrate. The display area DA and the non-display area NDA described in FIG. 1B may be defined similarly on the base layer BL.

The circuit element layer DP-CL may include at least one insulating layer and a circuit element. The insulating layer may include at least one inorganic layer and at least one organic layer. The circuit elements may include signal lines and a driving circuit of a pixel.

The display element layer DP-OLED may include a partition wall and light-emitting element. The light-emitting element may include an anode, an intermediate layer, and a cathode.

The thin film encapsulation layer TFE may include a plurality of multiple thin films. Some of these thin films may be disposed to enhance optical efficiency, while others may be disposed to protect organic light-emitting diodes.

The input sensor INS may acquire coordinate information from external inputs. The input sensor INS may have a multilayer structure. The input sensor INS may include a single-layer or multilayer conductive layer. Also, the input sensor INS may include a single-layer or multilayer insulating layer. The input sensor INS may detect external inputs using a capacitive method. However, this is only an example and the disclosure is not limited thereto. For example, in an embodiment, the input sensor INS may detect external inputs using electromagnetic induction or pressure-sensing methods. In another embodiment of the inventive concept, the input sensor INS may be omitted.

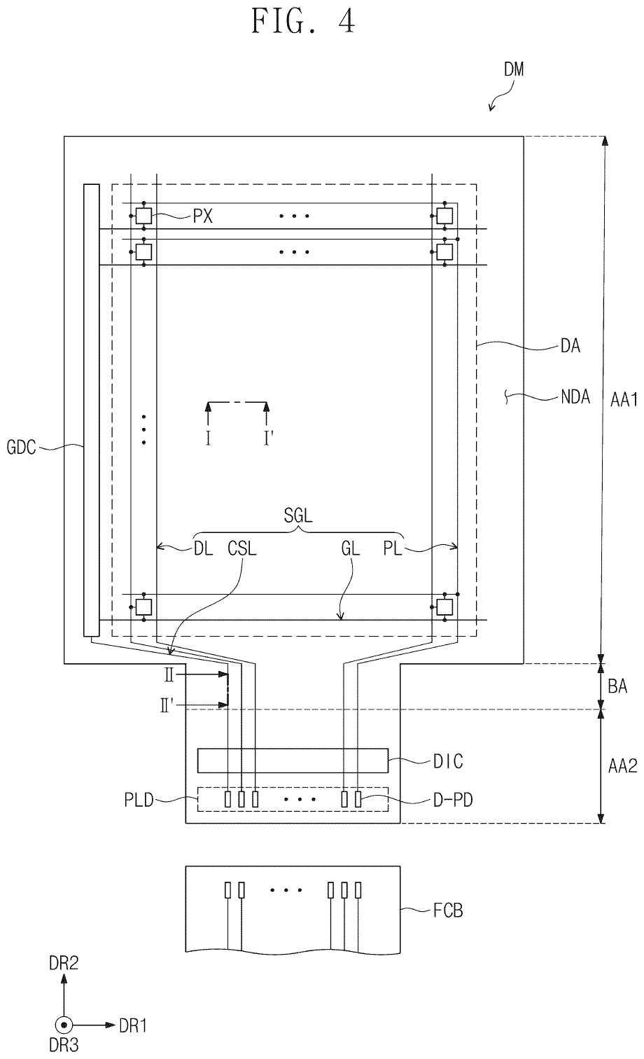

FIG. 4 is a plan view of the display module DM according to an embodiment of the inventive concept.

Referring to FIG. 4, the display module DM may have a display area DA and a non-display area NDA defined around at least a portion of the display area DA. The display module DM may include pixels PX and signal lines SGL electrically connected to the pixels PX. The display module DM may include a driving circuit GDC and a pad part PLD. The display area DA and the non-display area NDA may be distinguished based on the presence or absence of pixels PX. Pixels PX may be disposed on the display area DA. The driving circuit GDC and the pad part PLD may be disposed on the non-display area NDA.

The pixels PX may be arranged in the first direction DR1 and the second direction DR2. The pixels PX may include a plurality of pixel rows extending in the first direction DR1 and arranged in the second direction DR2, and a plurality of pixel columns extending in the second direction DR2 and arranged in the first direction DR1.

The signal lines SGL may include one or more of gate lines GL, data lines DL, power lines PL, or control signal lines CSL. Each gate line GL may be connected to a corresponding pixel among the pixels PX, and each data line DL may be connected to a corresponding pixel among the pixels PX. The power line PL may be electrically connected to the pixels PX. The control signal line CSL may be connected to the driving circuit GDC to provide control signals to the driving circuit GDC. The data lines DL, control signal lines CSL, and power lines PL may extend from the first area AA1 to the second area AA2, passing through the bending area BA.

The driving circuit GDC may include a gate driving circuit. The gate driving circuit may generate gate signals and output the gate signals to the gate lines GL. For example, the gate driving circuit may sequentially output the gate signals to the gate lines GL. The gate driving circuit may further output another control signal to a pixel driving circuit.

The pad part PLD may be a part to which the flexible circuit board FCB is connected. The pad part PLD may include pixel pads D-PD, which may be pads for connecting the flexible circuit board FCB to the display panel DP. Each of the pixel pads D-PD may be connected to a corresponding signal line among the signal lines SGL. The pixel pads D-PD may be connected to corresponding pixels PX through the signal lines SGL. Also, any one of the pixel pads D-PD may be connected to the driving circuit GDC.

The pad part PLD may further include input pads. The input pads may be pads for connecting the flexible circuit board FCB to the input sensor INS (see FIG. 2). However, the disclosure is not limited thereto, and the input pads may be disposed on the input sensor INS (see FIG. 2) and connected to a separate circuit board from the pixel pads D-PD. Alternatively, the input sensor INS (see FIG. 2) may be omitted, and the pad part PLD may not include the input pads.

The bending area BA and the second area AA2 may have a length in the first direction DR1, which is shorter than a length of the first area AA1 in the first direction DR1. The bending area BA may have a relatively short length in the first direction DR1, and the bending area BA may be more easily bend.

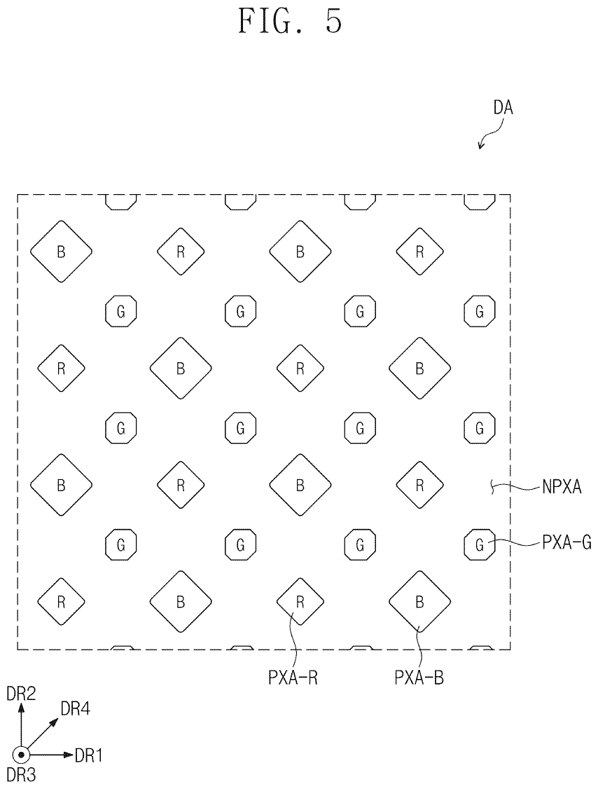

FIG. 5 is an enlarged plan view of a portion of the display area DA of the display module DM (see FIG. 3) according to an embodiment of the inventive concept. FIG. 5 illustrates a top-down view of the display module DM (see FIG. 1B) as seen from the display surface IS (see FIG. 1B), showing the arrangement of a first light-emitting area PXA-R, a second light-emitting area PXA-G, and a third light-emitting area PXA-B.

Referring to FIG. 5, the display area DA may include the first to third light-emitting areas PXA-R, PXA-G and PXA-B, and a peripheral area N PXA surrounding the first to third light-emitting areas PXA-R, PXA-G and PXA-B. The first to third light-emitting areas PXA-R, PXA-G and PXA-B may each correspond to an area in which light generated by the light-emitting elements may be emitted. The first to third light-emitting areas PXA-R, PXA-G and PXA-B may be distinguished based on the color of the light emitted toward the outside of the display module DM (see FIG. 2).

The first to third light-emitting areas PXA-R, PXA-G and PXA-B may respectively provide first to third colored lights of different colors. For example, the first colored light may be red light, the second colored light may be green light, and the third colored light may be blue light. However, the examples of the first to third colored lights are not limited thereto. For example, colored light including cyan light, magenta light, or yellow light, may be generated in the light-emitted areas.

Each of the first to third light-emitting areas PXA-R, PXA-G and PXA-B may be defined as an area in which a top surface of the anode may be exposed by a light-emitting opening, as described herein. The peripheral area NPXA may provide boundaries between the first to third light-emitting areas PXA-R, PXA-G and PXA-B and may reduce or prevent color mixing therebetween.”

A plurality of first to third light-emitting areas PXA-R, PXA-G and PXA-B may be provided and repeatedly arranged in a predetermined pattern within the display area DA. For example, the first and third light-emitting areas PXA-R and PXA-B may be alternately arranged along the first direction DR1 to provide a ‘first group.’ The second light-emitting areas PXA-G may be arranged along the first direction DR1 to provide a ‘second group.’ A plurality of the ‘first groups’ and ‘second groups’ may be provided, and the ‘first groups’ and ‘second groups’ may be alternately arranged along the second direction DR2.

A second light-emitting area of the second light-emitting areas PXA-G may be disposed spaced apart in the fourth direction DR4 from a first light-emitting area of the first light-emitting areas PXA-R or a third light-emitting area of the third light-emitting areas PXA-B. The fourth direction DR4 may be defined as a direction between the first and second directions DR1, DR2.

FIG. 5 illustrates an example of an arrangement of the first to third light-emitting areas PX A-R, PXA-G and PXA-B, however, the disclosure is not limited thereto. The first to third light-emitting areas may be arranged in various forms. In an embodiment, the first to third light-emitting areas PXA-R, PXA-G and PXA-B may have a Pentile™ arrangement as shown in FIG. 5. Alternatively, the first to third light-emitting areas PXA-R, PXA-G and PXA-B may have a stripe arrangement or a diamond (Diamond Pixel™) arrangement.

The first to third light-emitting areas PX A-R, PXA-G and PXA-B may have various shapes on a plane. For example, the first to third light-emitting areas PXA-R, PXA-G and PXA-B may have shapes such as polygons, circles, or ellipses. FIG. 5 illustrates an example of the first and third light-emitting areas PXA-R, PXA-B having a rectangular (or diamond) shape and the second light-emitting area PXA-G having an octagonal shape on the plane.

The first to third light-emitting areas PXA-R, PXA-G and PXA-B may have the same shape as each other on the plane, or at least one portion thereof may have different shapes from each other. FIG. 5 illustrates an example of the first and third light-emitting areas PXA-R, PXA-B having the same shape as each other on the plane, and the second light-emitting area PXA-G having a different shape from the first and third light-emitting areas PXA-R, PXA-B.

At least one portion of the first to third light-emitting areas PXA-R, PXA-G and PXA-B may have different areas from each other on the plane. In an embodiment, the first light-emitting area PXA-R in which red light is emitted may have a surface area greater than that of the second light-emitting area PXA-G in which green light is emitted PX A-G, and less than that of the third light-emitting area PXA-B in which blue light is emitted. However, the size relationship between the surface areas of the first to third light-emitting areas PXA-R, PXA-G and PXA-B depending on a color of the emitted light may not be limited thereto, and it may vary depending on the design of the display module DM (see FIG. 2). However, the disclosure is not limited thereto, and the first to third light-emitting areas PXA-R, PXA-G and PXA-B may have the same surface area on the plane.

The shapes, surface areas, or arrangements, of the first to third light-emitting areas PXA-R, PXA-G and PXA-B in the display module DM (see FIG. 2) may be designed in various ways depending on the color of the emitted light, the size, and the configuration of the display module DM (see FIG. 2), however, the disclosure is not limited thereto.

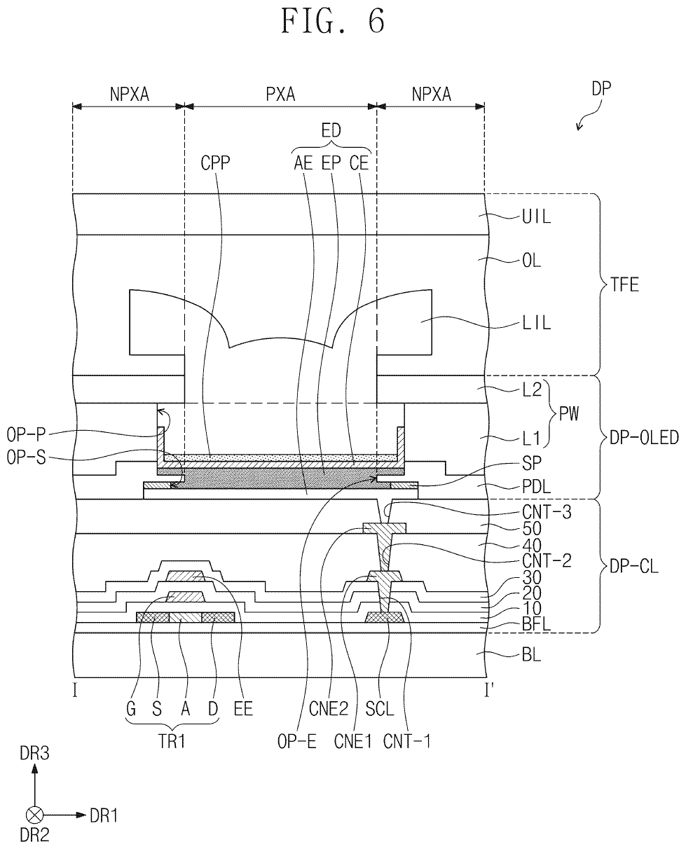

FIG. 6 is a cross-sectional view of the display panel taken along the line I-I′ of FIG. 4. In explaining FIG. 6, reference may be made to FIG. 3 and the explanation of the same reference numerals may be omitted or simplified. FIG. 6 is an enlarged view of one light-emitting area PX A within the display area DA (see FIG. 5), and the light-emitting area PXA in FIG. 6 may correspond to any one of the first to third light-emitting areas PXA-R, PXA-G and PXA-B shown in FIG. 5.

Referring to FIG. 6, the display panel DP may include a base layer BL, a circuit element layer DP-CL, a display element layer DP-OLED, and a thin film encapsulation layer TFE.

The display panel DP may include a plurality of insulating layers, a semiconductor pattern, a conductive pattern, and a signal line, however, the disclosure is not limited thereto. The insulating layer, the semiconductor layer, and the conductive layer may be provided by coating, deposition, or other methods. The insulating layer, the semiconductor layer, and the conductive layer may be selectively patterned by photolithography and etching. In this manner, the semiconductor pattern, conductive pattern, and signal line, included in the circuit element layer DP-CL and the display element layer DP-OLED may be provided.

The circuit element layer DP-CL may be disposed on the base layer BL. The circuit element layer DP-CL may include a buffer layer BFL, a transistor TR1, a signal transmission region SCL, first to fifth insulating layers 10, 20, 30, 40 and 50, an electrode EE, and a plurality of connection electrodes CNE1 and CNE2.

The buffer layer BFL may be disposed on the base layer BL. The buffer layer BFL may enhance the bonding strength between the base layer BL and the semiconductor pattern. The buffer layer BFL may include a silicon oxide layer and a silicon nitride layer. The silicon oxide layer and the silicon nitride layer may be alternately stacked.

A semiconductor pattern may be disposed on the buffer layer BFL. The semiconductor pattern may include polysilicon. However, the semiconductor pattern is not limited thereto and may also include, for example, amorphous silicon or metal oxides. The semiconductor pattern in FIG. 6 is an example, and additional semiconductor patterns may be further disposed in a plurality of light-emitting areas PXA-R, PXA-G and PXA-B (see FIG. 5). The semiconductor patterns may be arranged in a specific pattern across a plurality of light-emitting areas PXA-R, PXA-G and PXA-B. The semiconductor pattern may have various electrical properties depending on whether the semiconductor pattern is doped. The semiconductor pattern may include a first region having a relatively high doping concentration and a second region having a relatively low doping concentration. The first region may be doped with an N-type dopant or a P-type dopant. A P-type transistor may include a first region doped with a P-type dopant.

The first region may have higher conductivity than that of the second region and may function as an electrode or signal line. The second region may correspond to the active area (or channel) of the transistor. In other words, a portion of the semiconductor pattern may be the active area of the transistor, another portion may be the source or drain of the transistor, and another portion may be a conductive region.

A source S, an active area A, and a drain D of the transistor TR1 may be provided from the semiconductor pattern. FIG. 6 illustrates a portion of a signal transmission region SCL provided from the semiconductor pattern. The signal transmission region SCL may be connected to the drain D of the transistor TR1 on the plane.

The first to fifth insulating layers 10, 20, 30, 40 and 50 may be disposed on the buffer layer BFL. The first to fifth insulating layers 10, 20, 30, 40 and 50 may be inorganic or organic layers.

The first insulating layer 10 may be disposed on the buffer layer BFL. The first insulating layer 10 may cover the source S, the active area A, the drain D, and the signal transmission region SCL of the transistor TR1 disposed on the buffer layer BFL. A gate G of the transistor TR1 may be disposed on the first insulating layer 10. The gate G of the transistor TR1 may be disposed above the active area A and between the source S and drain D on a plane. The second insulating layer 20 may be disposed on the first insulating layer 10 to cover the gate G. An electrode EE may be disposed on the second insulating layer 20. The third insulating layer 30 may be disposed on the second insulating layer 20 to cover the electrode EE.

The first connection electrode CNE1 may be disposed on the third insulating layer 30. The first connection electrode CNE1 may be connected to the signal transmission region SCL through a contact hole CNT-1 that penetrates through the first to third insulating layers 10, 20 and 30. The fourth insulating layer 40 may be disposed on the third insulating layer 30 to cover the first connection electrode CNE1. The fourth insulating layer 40 may be an organic layer.

The second connection electrode CNE2 may be disposed on the fourth insulating layer 40. The second connection electrode CNE2 may be connected to the first connection electrode CNE1 through a contact hole CNT-2 that penetrates through the fourth insulating layer 40. The fifth insulating layer 50 may be disposed on the fourth insulating layer 40 to cover the second connection electrode CNE2. The fifth insulating layer 50 may be an organic layer.

The display element layer DP-OLED may be disposed on the circuit element layer DP-CL. The display element layer DP-OLED may include a light-emitting element ED, a sacrificial pattern SP, a pixel defining layer PDL, and a partition wall PW.

The light-emitting element ED may include an anode AE (or a first electrode), a light-emitting pattern EP, and a cathode CE (or a second electrode). The light-emitting element ED may be disposed within a light-emitting opening OP-E and a partition wall opening OP-P, which will be described herein.

The anode A E may be disposed on the fifth insulating layer 50 of the circuit element layer DP-CL. The anode AE may be a transparent electrode, a semi-transparent electrode, or a reflective electrode. The anode A E may be connected to the second connection electrode CNE2 through a connection contact hole CNT-3 defined through the fifth insulating layer 50. The anode AE may be electrically connected to the signal transmission region SCL through the first and second connection electrodes CNE1 and CNE2, and be electrically connected to the corresponding circuit element through the signal transmission region SCL. The anode AE may have a single-layer or multilayer structure. The anode A E may include a plurality of layers including layers such as ITO and Ag. For example, the anode AE may include a layer containing ITO (hereinafter, referred to as a lower ITO layer), a layer containing Ag disposed on the lower ITO layer (hereinafter, referred to as an Ag layer), and a layer containing ITO disposed on the Ag layer (hereinafter, referred to as an upper ITO layer).

The sacrificial pattern SP may be disposed between the anode A E and the pixel defining layer PDL in the third direction DR3. For example, the sacrificial pattern SP may be disposed on an upper surface of the anode A E and on a lower surface of the pixel defining layer PDL. The sacrificial pattern SP may have a sacrificial opening OP-S that exposes a portion of a top surface of the anode A E. The sacrificial opening OP-S may overlap the light-emitting opening OP-E, which will be described herein.

The pixel defining layer PDL may be disposed on the fifth insulating layer 50 of the circuit element layer DP-CL. The pixel defining layer PDL may have a light-emitting opening OP-E defined therein. The light-emitting opening OP-E may correspond to the anode A E, and the pixel defining layer PDL may expose at least a portion of the anode A E through the light-emitting opening OP-E.

Also, the light-emitting opening OP-E may correspond to the sacrificial opening OP-S of the sacrificial pattern SP. For example, the light-emitting opening OP-E may be aligned with the sacrificial opening OP-S in the third direction DR3. According to an embodiment of the inventive concept, the top surface of the anode A E may be spaced apart from a portion of the pixel defining layer PDL in a cross-section view, with the sacrificial pattern SP disposed therebetween, and the anode A E may be protected from damage during a formation process of the light-emitting opening OP-E.

On the plane, the light-emitting opening OP-E may have a surface area that is less than a surface area of the sacrificial opening OP-S. That is, an inner surface of the pixel defining layer PDL that defines the light-emitting opening OP-E may be relatively adjacent to the center of the anode AE as compared to an inner surface of the sacrificial pattern SP that defines the sacrificial opening OP-S. However, the disclosure is not limited thereto, and the inner surface of the sacrificial pattern SP that defines the sacrificial opening OP-S may be substantially aligned with the inner surface of the pixel defining layer PDL that defines the light-emitting opening OP-E. Here, the light-emitting area PXA may be considered as the area of the anode A E exposed from the corresponding sacrificial opening OP-S.

The pixel defining layer PDL may include an insulating material. For example, it may include silicon nitride (SᵢNₓ), or silicon nitride. In an embodiment, the pixel defining layer PDL that overlaps the first area AA1 on which the pixel PX is disposed and the bending area BA may include an inorganic material. In another embodiment, the pixel defining layer PDL that overlaps the first area AA1 may include an inorganic material, while the pixel defining layer PDL that overlaps the bending area BA may include an organic material.

The pixel defining layer PDL may be disposed between the anode AE and the partition wall PW, which may prevent the anode AE and the partition wall PW from being electrically connected.

The light-emitting pattern EP may be disposed on the anode A E. The light-emitting pattern EP may include a light-emitting layer that includes light-emitting material. The light-emitting pattern EP may further include a hole injection layer and a hole transport layer disposed between the anode A E and the light-emitting layer of the light-emitting pattern EP. The light-emitting pattern EP may further include an electron transport layer and an electron injection layer disposed between the cathode CE and the light-emitting layer of the light-emitting pattern EP. The light-emitting pattern EP may be referred to as an “organic layer” or “intermediate layer.”

The light-emitting pattern EP may be may overlap an upper tip portion defined by a second partition wall layer L2 of the partition wall PW. The light-emitting pattern EP may have a shape defined by a tip portion of the pixel defining layer PDL defining the light-emitting opening OP-E on a plane. Further details will be described herein in a method of manufacturing the display panel. The light-emitting pattern EP may be disposed inside the sacrificial opening OP-S and the light-emitting opening OP-E. However, this is only an example, and the light-emitting pattern EP may be disposed inside at least one of the sacrificial opening OP-S, the light-emitting opening OP-E, or the partition wall opening OP-P. The light-emitting pattern EP may cover a portion of the top surface of the pixel defining layer PDL. For example, the light-emitting pattern EP may cover a portion of the top surface of the pixel defining layer PDL defining the light-emitting opening OP-E.

The cathode CE may be disposed on the light-emitting pattern EP. The cathode CE may be defined by a portion of the partition wall PW. At least a portion of the cathode CE may be disposed in the partition wall opening OP-P. FIG. 6 illustrates an example in which the cathode CE is disposed within the partition wall opening OP-P, however the disclosure is not limited thereto. For example, the cathode CE may be disposed only within the partition wall opening OP-P. The cathode CE may overlap the upper tip portion defined by the second partition wall layer L2 of the partition wall PW on a plane.

The cathode CE may include a first portion extending along an upper surface of the light-emitting pattern EP and a second portion extending along a first inner surface of a first partition wall layer L1, wherein an end portion of the cathode CE may contact the first partition wall layer L1. For example, the cathode CE may have a U shape in cross section wherein the first portion has a first thickness and the second portion has a second thickness greater than the first thickness. FIG. 6 illustrates an example in which the cathode CE contacts both the first inner surface of the first partition wall layer L1 and the inner surface of the pixel defining layer PDL, however the disclosure is not limited thereto. For example, the cathode CE may only contact the first inner surface of the first partition wall layer L1. In another examiner, the second portion of the cathode CE may be omitted, and the first portion may include end portions disposed between the pixel defining layer PDL and the first partition wall layer L1.

The cathode CE may be a conductive material. The cathode CE may be provided by various materials as long as the material has conductivity, such as metal, transparent conductive oxide (TCO), or conductive polymer material. For example, the cathode CE may include silver (Ag), magnesium (Mg), lead (Pb), or copper (Cu), or compounds thereof.

In an embodiment of the inventive concept, the display element layer DP-OLED may further include a capping pattern CPP. The capping pattern CPP may be disposed within the partition wall opening OP-P and may be disposed on the cathode CE. For example, the capping pattern CPP may be disposed on an upper surface of the first portion of the cathode CE and may contact inner surfaces of the second portion of the cathode CE. The capping pattern CPP may be overlap the upper tip portion defined in the partition wall PW on a plane. In an embodiment, the capping pattern CPP may be omitted.

The partition wall PW may be disposed on the pixel defining layer PDL. The partition wall opening OP-P may be defined in the partition wall PW. The partition wall opening OP-P may overlap the light-emitting opening OP-E and may expose at least a portion of the light-emitting pattern EP.

The partition wall PW may include multiple layers sequentially stacked. For example, the partition wall PW may include a first partition wall layer L1 and the second partition wall layer L2. The first partition wall layer L1 may be disposed on the pixel defining layer PDL, and the second partition wall layer L2 may be disposed on the first partition wall layer L1. As shown in FIG. 5, the first partition wall layer L1 may have a thickness greater than a thickness of the second partition wall layer L2, however the disclosure is not limited thereto.

The first partition wall layer L1 and the second partition wall layer L2 may each include a conductive material. For example, the conductive material may include metal or transparent conductive oxide (TCO), or a combination thereof. For example, the metal may include gold (Au), silver (Ag), aluminum (AI), magnesium (M g), lithium (Li), molybdenum (Mo), titanium (Ti), or copper (Cu), or alloys. The transparent conductive oxide may include indium tin oxide (ITO), indium zinc oxide (IZO), zinc oxide, indium oxide, indium gallium oxide, indium gallium zinc oxide (IGZO), or aluminum zinc oxide.

The partition wall PW may have an undercut shape in cross-section. At least one layer of the multiple layers of the partition wall PW may be recessed compared to the other layers, wherein the second partition wall layer L2 defines the upper tip portion in the partition wall PW. For example, the first partition wall layer L1 may have an undercut shape relative to the second partition wall layer L2. The second partition wall layer L2 may protrude toward the light-emitting opening OP-E more than the first partition wall layer L1, defining the upper tip portion. A portion protruding from the first partition wall layer L1 toward the light-emitting area PX A may be defined as the upper tip portion within the partition wall PW. In other words, a second inner surface of the second partition wall layer L2 may extend toward the center of the anode A E than the first inner surface of the first partition wall layer L1. The second partition wall layer L2 and the light-emitting opening OP-E may have aligned inner surfaces, coinciding with the light-emitting area PXA, however the disclosure is not limited thereto. For example, inner surfaces of the second partition wall layer L2 and the light-emitting opening OP-E may be offset from one another.

For example, in FIG. 6, the first inner surface of the first partition wall layer L1 and the second inner surface of the second partition wall layer L2 may be perpendicular to the top surface of the pixel defining layer PDL, however the disclosure is not limited thereto. For example, the partition wall PW may have a tapered shape or an inverted tapered shape.

In the display area DA (see FIG. 4), the partition wall PW may be electrically connected to the cathode CE. The partition wall PW in the display area DA may have an integrated shape, which may be a connected shape. For example, the integrated shape of the partition wall PW in a specific area may refer to a shape that is integrally connected without any patterns across the entire specific area. The partition wall PW may receive a driving voltage, and the cathode CE may be electrically connected to the partition wall PW to receive the driving voltage.

The thin film encapsulation layer TFE may be disposed on the display element layer DP-OLED. The thin film encapsulation layer TFE may include a lower inorganic encapsulation pattern LIL, an organic encapsulation layer OL, and an upper inorganic encapsulation layer UIL.

The lower inorganic encapsulation pattern LIL may overlap at least a portion the light-emitting opening OP-E. The lower inorganic encapsulation pattern LIL may be disposed on the capping pattern CPP and may cover the light-emitting element ED. A first portion of the lower inorganic encapsulation pattern LIL may be provided on the partition wall opening OP-P and the first partition wall layer L1 of the partition wall PW, and a second portion of the lower inorganic encapsulation pattern LIL may be provided on the second partition wall layer L2 of the partition wall PW. For example, a portion of the first portion of the lower inorganic encapsulation pattern LIL may be disposed below the second partition wall layer L2 of the partition wall PW.

The organic encapsulation layer OL may be disposed on the lower inorganic encapsulation pattern LIL. The organic encapsulation layer OL may cover the lower inorganic encapsulation pattern LIL. The organic encapsulation layer OL may provide a flat top surface. The upper inorganic encapsulation layer UIL may be disposed on the organic encapsulation layer OL.

The lower inorganic encapsulation pattern LIL and the upper inorganic encapsulation layer UIL may protect the display element layer DP-OLED from moisture and oxygen, while the organic encapsulation layer OL may protect the display element layer DP-OLED from foreign substances such as dust particles.

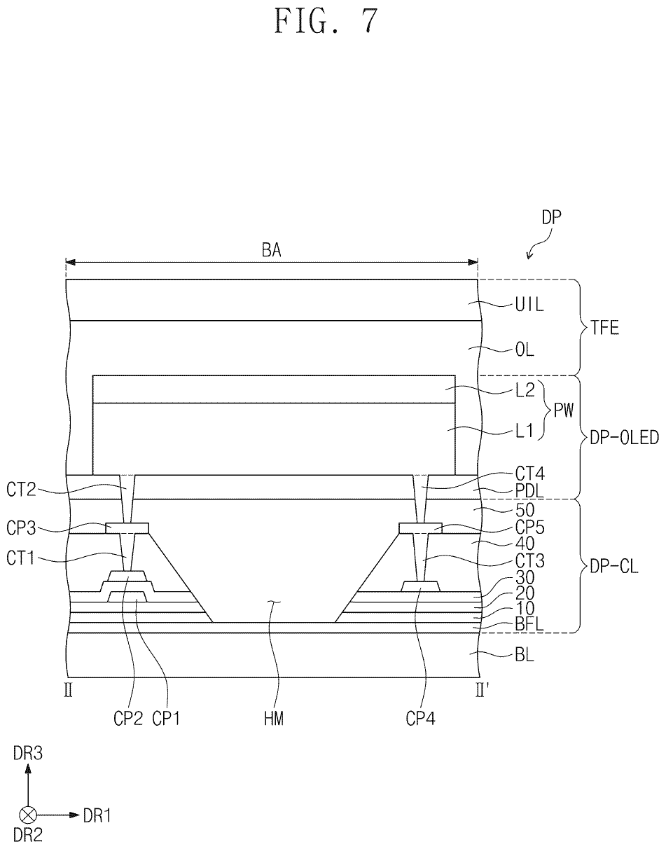

FIG. 7 is a cross-sectional view of the display panel DP taken along the line II-II′ of FIG. 4. FIG. 7 illustrates a cross-section view of an area corresponding to the bending area BA in the display panel DP. In explaining FIG. 7, it will be described with reference to FIG. 6, and the explanation of the same reference numerals may be omitted or simplified.

Referring to FIG. 6 and FIG. 7, the circuit element layer DP-CL may include conductive patterns CP1, CP2, CP3, CP4 and CP5, and the first to fifth insulating layers 10, 20, 30, 40 and 50 that cover the conductive patterns CP1, CP2, CP3, CP4 and CP5. The circuit element layer DP-CL overlapping the bending area BA may include a first conductive pattern CP1, a second conductive pattern CP2, a third conductive pattern CP3, a fourth conductive pattern CP4, and a fifth conductive pattern CP5. A groove HM may be defined in the buffer layer BFL and the first to fifth insulating layers 10, 20, 30, 40 and 50 of the circuit element layer DP-CL. The groove HM may overlap the bending area BA. The partition wall PW overlapping the bending area BA may be electrically connected to first to fifth conductive patterns CP1, CP2, CP3, CP4 and CP5 and may be patterned to form a bridge wiring structure in the bending area BA.

The first conductive pattern CP1 may be disposed on the second insulating layer 20 and covered by the third insulating layer 30. The second conductive pattern CP2 and the fourth conductive pattern CP4 may be disposed on the third insulating layer 30 and covered by the fourth insulating layer 40. The third conductive pattern CP3 and the fifth conductive pattern CP5 may be disposed on the fourth insulating layer 40 and covered by the fifth insulating layer 50.

The first conductive pattern CP1 may be disposed on the same layer as the electrode EE. The first conductive pattern CP1 and the electrode EE may be formed through the same process. The second conductive pattern CP2 and the fourth conductive pattern CP4 may be disposed on the same layer as the first connection electrode CNE1 and formed through the same process. The third conductive pattern CP3 and the fifth conductive pattern CP5 may be disposed on the same layer as the second connection electrode CNE2 and formed through the same process. However, this is only an example and the disclosure is not limited thereto.

The third conductive pattern CP3 may be connected to the second conductive pattern CP2 through the first contact hole CT1 passing through the fourth insulating layer 40, and the partition wall PW may be connected to the third conductive pattern CP3 through the second contact hole CT2 passing through the pixel defining layer PDL and the fifth insulating layer 50. The partition wall PW overlapping the bending area BA may be connected to the conductive pattern CP2 through the first contact hole CT1 and the second contact hole CT2 passing through the fourth insulating layer 40 and the fifth insulating layer 50 of the circuit element layer DP-CL. For example, the partition wall PW may be electrically connected to the second conductive pattern CP2 through the first and second contact holes CT1 and CT2.

The fifth conductive pattern CP5 may be connected to the fourth conductive pattern CP4 through the third contact hole CT3 passing through the fourth insulating layer 40, and the partition wall PW may be connected to the fifth conductive pattern CP5 through the fourth contact hole CT4 passing through the pixel defining layer PDL and the fifth insulating layer 50. The partition wall PW overlapping the bending area BA may be connected to the conductive pattern CP4 through third contact hole CT3 and the fourth contact hole CT4 passing through the fourth insulating layer 40 and the fifth insulating layer 50 of the circuit element layer DP-CL. For example, the partition wall PW may be electrically connected to the fourth conductive pattern CP4 through the third and fourth contact holes CT3, CT4.

The partition wall PW overlapping the first non-bending area AA1 may be electrically connected so that the cathode CE (see FIG. 6) may receive the driving voltage. The partition wall PW overlapping the bending area BA may be electrically connected to first to fifth conductive patterns CP1, CP2, CP3, CP4 and CP5 (see FIG. 7). The driving voltage, or another signal, may be applied from the second area AA2 to the first area AA1 through the bending area BA using the partition wall PW and the first to fifth conductive patterns CP1, CP2, CP3, CP4 and CP5 (see FIG. 7). The partition wall PW overlapping the bending area BA may be patterned to form a bridge wiring structure. The partition wall PW overlapping the bending area BA and patterned to form the bridge wiring structure may bridge the groove HM. The partition wall PW overlapping the bending area BA may be disposed on an upper surface of the pixel defining layer PDL. Portions of the partition wall PW forming the bridge wiring structure may be surrounded by the organic encapsulation layer OL.

The partition wall PW and the first to fifth conductive patterns CP1, CP2, CP3, CP4 and CP5 may provide a first signal line of the signal lines SGL and a second signal line of the signal lines SGL disconnected from the first signal line. For example, the partition wall PW and the first to fifth conductive patterns CP1, CP2, CP3, CP4 and CP5 may be patterned to provide the first and second signal lines of the signal lines SGL extending substantially in parallel through the bending area BA. For example, the signal lines SGL may extend substantially in parallel through the bending area BA may not cross one another. The partition wall PW included in the first signal line of the signal lines SGL and the partition wall PW included in the second signal line of the signal lines SGL may be space apart from each other. For example, the partition wall PW included in the first signal line of the signal lines SGL and the partition wall PW included in the second signal line of the signal lines SGL may have physically separated shapes. For example, the partition wall PW may be patterned to form a plurality of signal lines including the first signal line and the second signal line of the signal lines SGL. For example, the partition wall electrically connected to the conductive patterns forming the control signal line CSL may be electrically disconnected from the partition wall electrically connected to the conductive patterns forming the data lines DL.

FIG. 7 illustrates an example in which the first to fifth conductive patterns CP1, CP2, CP3, CP4 and CP5 and the partition wall PW form portions of the control signal line CSL (see FIG. 4), however the disclosure is not limited thereto. For example, the first to fifth conductive patterns CP1, CP2, CP3, CP4 and CP5 and the partition wall PW in FIG. 7 may form portions of a data line DL, or a power line PL passing through the bending area BA (see FIG. 4). Further, the first to fifth conductive patterns CP1, CP2, CP3, CP4 and CP5 and the partition wall PW in FIG. 7 may form portions of a gate line GL in the first area AA1.

Additionally, FIG. 7 illustrates an example in which the electrical connection of the first to fifth conductive patterns CP1, CP2, CP3, CP4 and CP5 may be provided by the partition wall PW, however the disclosure is not limited thereto. For example, the first to fifth conductive patterns CP1, CP2, CP3, CP4 and CP5 may be connected by a connecting conductive pattern disposed on the fifth insulating layer 50 to provide the signal line SGL.

The partition wall PW and the first to fifth conductive patterns CP1, CP2, CP3, CP4 and CP5 may include the same conductive material. For instance, the partition wall PW and the first to fifth conductive patterns CP1, CP2, CP3, CP4 and CP5 may include titanium (Ti), aluminum (Al), molybdenum (Mo), or titanium nitride (TiN). Further, the partition wall PW disposed in the first area AA1, the second area AA2, and the bending area BA may include the same conductive material. For example, the partition wall PW disposed in the first area AA1, the second area AA2, and the bending area BA may be formed at a same time. M ore particularly, the first partition wall layer L1 of the partition wall PW may be formed in the first area AA1, the second area AA2, and the bending area BA at a first time and the second partition wall layer L2 of the partition wall PW may be formed in the first area AA1, the second area AA2, and the bending area BA at a second time.

Referring to FIG. 2, FIG. 6, and FIG. 7, when the partition wall PW of the display element layer DP-OLED is used as wiring to connect the first to fifth conductive patterns CP1, CP2, CP3, CP4 and CP5 of the circuit element layer DP-CL, the curvature radius R1 of the bending area BA may be increased by the thickness of the pixel defining layer PDL. For example, the curvature radius R1 may be increased by about 1 to about 3 micrometers when compared to a case in which a conductive pattern disposed on the fifth insulating layer 50 is used as the connecting wiring. In a case of an increased curvature radius R1, a tensile force acting on the bending area BA of the display module DM may be reduced, and cracks occurring in the bending area BA may be decreased or eliminated.

As described herein, when the partition wall of the display element layer is used as wiring to connect the conductive patterns of the circuit element layer, the curvature radius of the bending area may be increased by the thickness of the pixel defining layer, and the tensile force acting on the bending area of the display module may be reduced, and cracks occurring in the bending area may be decreased or eliminated.

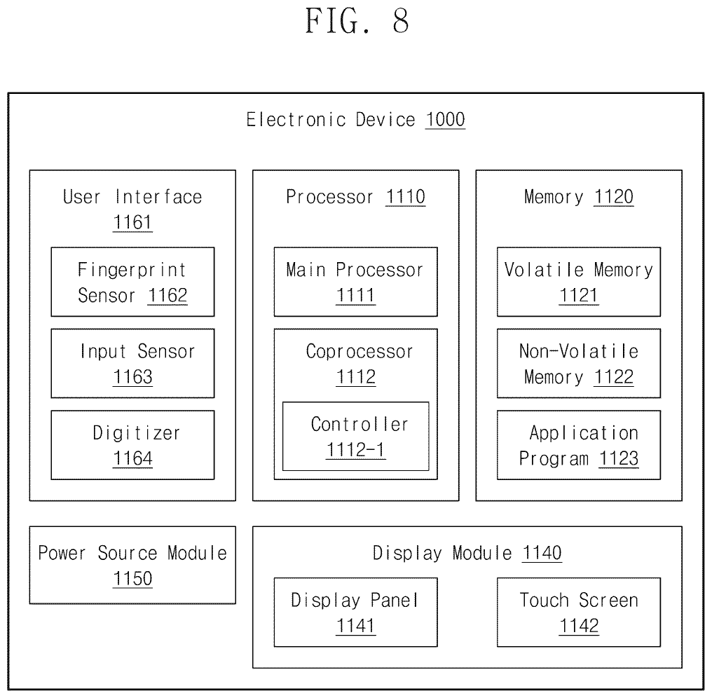

FIG. 8 is a diagram illustrating an electronic device according to an embodiment of the inventive concept. Referring to FIG. 8, the electronic device 1000 according to an embodiment of the inventive concept may output various information (e.g., images, text, music, etc.) through a display module 1140, which, for example, may correspond to the display device DD shown in FIG. 1A (for example, the display module 1140 may be the display module DM in FIG. 1B). When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device DD shown in FIG. 1A (for example, the display module 1140 may be the display module DM in FIG. 1B).

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display device DD shown in FIG. 1A.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PM IC). The PM IC may supply optimized power source to each of the components described above including the display module 1140.

Although embodiments of the inventive concept have been described, it is understood that the inventive concept should not be limited, but various changes and modifications can be made by one ordinary skilled in the art within the spirit and scope of the inventive concept as hereinafter claimed.

Therefore, the technical scope of the inventive concept should not be limited to the contents described in the detailed description of the specification but should be defined by the claims.

What is claimed is:

1. A display module comprising:
a base layer on which a first area, a bending area, and a second area are defined along one direction;
a circuit element layer disposed on the base layer, the circuit element layer comprising a conductive pattern and insulating layers configured to cover the conductive pattern; and
a display element layer disposed on the circuit element layer,
wherein the display element layer comprises:
a pixel defining layer disposed on the circuit element layer, having a light-emitting opening in an area overlapping the first area;
a partition wall disposed on the pixel defining layer and having a partition wall opening overlapping the light-emitting opening; and
a light-emitting element comprising an anode, a light-emitting pattern, and a cathode that is in contact with the partition wall and disposed in the light-emitting opening and the partition wall opening,
wherein the partition wall overlapping the bending area is connected to the conductive pattern through a contact hole passing through the insulating layers of the circuit element layer.

2. The display module of claim 1, wherein the base layer comprises a display area and a non-display area adjacent to the display area, and
the first area corresponds to the display area and a portion of the non-display area, and the bending area and the second area correspond to the non-display area.

3. The display module of claim 2, wherein the partition wall is electrically connected to the cathode in the display area.

4. The display module of claim 2, wherein the partition wall in the display area has an integrated shape.

5. The display module of claim 1, wherein the partition wall and the conductive pattern are patterned to provide a first signal line and a second signal line that is electrically disconnected from the first signal line.

6. The display module of claim 5, wherein the first signal line and the second signal line are spaced apart from each other.

7. The display module of claim 1, wherein the partition wall overlapping the bending area is electrically disconnected from the cathode.

8. The display module of claim 1, wherein the circuit element layer comprises a plurality of insulating layers, and
a groove that overlaps the bending area is defined in the plurality of insulating layers.

9. The display module of claim 1, wherein the conductive pattern comprises a first conductive pattern and a second conductive pattern disposed on the first conductive pattern, and the insulating layers include a first insulating layer configured to cover the first conductive pattern and a second insulating layer configured to cover the second conductive pattern,
wherein the second conductive pattern is connected to the first conductive pattern through a first contact hole defined in the first insulating layer, and the partition wall is connected to the second conductive pattern through a second contact hole defined in the second insulating layer.

10. The display module of claim 1, wherein the partition wall and the conductive pattern comprise a same conductive material.

11. The display module of claim 1, wherein each of the partition wall and the conductive pattern comprises at least one of titanium (Ti), aluminum (AI), molybdenum (Mo), or titanium nitride (TiN).

12. The display module of claim 1, wherein the partition wall comprises:
a first partition wall layer disposed on the pixel defining layer and defining the partition wall opening; and
a second partition wall layer disposed on the first partition wall layer,
wherein the second partition wall layer comprises an upper tip portion protruding from the first partition wall layer into the partition wall opening.

13. The display module of claim 10, wherein the first partition wall layer has an undercut shape with respect to the second partition wall layer.

14. The display module of claim 1, further comprising:
a thin film encapsulation layer disposed on the display element layer,
wherein the thin film encapsulation layer comprises:
a lower inorganic encapsulation pattern configured to cover the light-emitting element;
an organic encapsulation layer disposed on the lower inorganic encapsulation pattern; and
an upper inorganic encapsulation layer disposed on the organic encapsulation layer.

15. An electronic device comprising:
a display module on which a first area, a bending area, and a second area are defined along one direction;
a window disposed on the display module; and
a housing disposed below the display module and coupled to the window to provide an internal space;
wherein the display module comprises:
a circuit element layer comprising a conductive pattern and insulating layers configured to cover the conductive pattern;
a pixel defining layer disposed on the circuit element layer and having a light-emitting opening in an area overlapping the first area on a plane;
a partition wall disposed on the pixel defining layer and having a partition wall opening overlapping the light-emitting opening; and
a light-emitting element comprising an anode, a light-emitting pattern, and a cathode that is in contact with the partition wall and disposed within the light-emitting opening and the partition wall opening,
wherein the partition wall and the conductive pattern are patterned to provide a first signal line and a second signal line that is electrically disconnected from, and spaced apart from, the first signal line.

16. The electronic device of claim 15, wherein the display module comprises a display area and a non-display area adjacent to the display area,
the first area corresponds to the display area and a portion of the non-display area, and the bending area and the second area correspond to the non-display area, and
in the display area, the partition wall has an integrated shape and is electrically connected to the cathode.

17. The electronic device of claim 15, wherein the partition wall overlapping the bending area is electrically disconnected from the cathode.

18. The electronic device of claim 15, wherein the circuit element layer comprises a plurality of insulating layers, and
a groove that overlaps the bending area is defined in the plurality of insulating layers.

19. The electronic device of claim 15, wherein the partition wall and the conductive pattern comprise a same conductive material.

20. The electronic device of claim 15, wherein the partition wall comprises a first partition wall layer defining the partition wall opening and disposed on the pixel defining layer and a second partition wall layer disposed on the first partition wall layer,
wherein the second partition wall layer comprises an upper tip portion protruding from the first partition wall layer into the partition wall opening.
